(19) United States
(12) Patent Application Publication
(10) Pub. No.: US 2025/0349781 A1
(43) Pub. Date: Nov. 13, 2025

(54) SEMICONDUCTOR PACKAGE AND MANUFACTURING METHOD OF THE SAME

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 19/025,700

(22) Filed: Jan. 16, 2025

(30) Foreign Application Priority Data
May 9, 2024 (KR) 10-2024-0061338

(51) Int. Cl. H01L 23/00; H01L 23/31; H01L 25/07

(52) U.S. Cl. CPC H01L 24/24; H01L 24/19; H01L 24/48; H01L 24/73; H01L 25/074; H01L 23/3107; H01L 2224/19; H01L 2224/244; H01L 2224/48227; H01L 2224/73227; H01L 2225/06562

(57) ABSTRACT

Provided is a semiconductor package including: a semiconductor chip stack; a lower redistribution structure spaced apart from the chip stack; a connection structure between the lower redistribution structure and the chip stack and in contact with the lower redistribution structure; conductive wires connecting the chips to the connection structure; and an encapsulant surrounding the chip stack, the connection structure, and the conductive wires, wherein the connection structure includes a connection insulating layer, a connection pattern in contact with the connection insulating layer, and metal layers, wherein the connection pattern includes a connection line pattern and a connection via pattern, wherein the lower redistribution structure includes a redistribution insulating layer and a redistribution pattern, and wherein the metal layers correspond to the conductive wires, are on one surface of the connection via pattern, and are between the conductive wires and the connection via pattern.

### CROSS-REFERENCE TO RELATED APPLICATION

This application is based on and claims priority to Korean Patent Application No. 10-2024-0061338, filed on May 9, 2024, in the Korean Intellectual Property Office, the disclosure of which is incorporated by reference herein in its entirety.

### BACKGROUND

### 1. Field

The disclosure relates to a semiconductor package and a manufacturing method of the same, and more particularly, to a semiconductor package including a semiconductor chip stack including stacked semiconductor chips and a manufacturing method of the same.

### 2. Description of Related Art

In accordance with the rapid development of the electronics industry and the needs of users, electronic devices are becoming smaller and lighter. High integration and large capacity of semiconductor devices, which are core components of electronic devices, are also required, but integration of semiconductor devices is reaching its limits. Accordingly, to achieve large capacity semiconductor devices, a semiconductor package including a plurality of semiconductor chips is being developed. As the demand for large capacity semiconductor devices increases, a semiconductor package including a plurality of semiconductor chips which are stacked therein is being developed.

The semiconductor package including a plurality of semiconductor chips which are stacked therein includes a package in which a plurality of semiconductor chips are vertically stacked on a package substrate. In order to provide a single semiconductor package including stacked semiconductor chips, a semiconductor package is used in which a plurality of semiconductor chips are stacked and electrical input and output are performed through wires between the plurality of chips and the package substrate.

### SUMMARY

Provided is a semiconductor package and a manufacturing method of same configured to prevent contamination of semiconductor packages and manufacturing facilities and improve the reliability of semiconductor packages.

According to an aspect of the disclosure, a semiconductor package includes: a semiconductor chip stack including a stack of a plurality of semiconductor chips; a lower redistribution structure spaced apart from the semiconductor chip stack; a connection structure between the lower redistribution structure and the semiconductor chip stack, wherein the connection structure is in contact with the lower redistribution structure; conductive wires connecting the plurality of semiconductor chips to the connection structure; and an encapsulant surrounding at least a portion of a surface of the semiconductor chip stack, an upper surface of the connection structure, and a side surface of the conductive wires, wherein the connection structure includes a connection insulating layer, a connection pattern in contact with the connection insulating layer, and metal layers, wherein the connection pattern includes a connection line pattern and a connection via pattern, wherein the lower redistribution structure includes a redistribution insulating layer and a redistribution pattern, and wherein the metal layers correspond to the conductive wires, are on one surface of the connection via pattern, and are between the conductive wires and the connection via pattern.

According to an aspect of the disclosure, a semiconductor package includes: a semiconductor chip stack including a plurality of semiconductor chips; a lower redistribution structure spaced apart from the semiconductor chip stack; conductive wires connecting the plurality of semiconductor chips to the lower redistribution structure; and an encapsulant surrounding at least a portion of a surface of the semiconductor chip stack, an upper surface of the lower redistribution structure, and a side surface of the conductive wires, wherein the lower redistribution structure includes a redistribution insulating layer, a redistribution pattern, a top insulating layer, a connection insulating layer, a connection pattern, and metal layers, wherein the connection pattern includes a connection line pattern and a connection via pattern, wherein the top insulating layer is in contact with the encapsulant, wherein the encapsulant is between the semiconductor chip stack and the lower redistribution structure, and wherein the metal layers correspond to the conductive wires, are on one surface of the connection via pattern, and are between the conductive wires and the connection via pattern.

According to an aspect of the disclosure, a semiconductor package includes: a semiconductor chip stack including a plurality of semiconductor chips and a plurality of chip pads on lower surfaces the plurality of semiconductor chips, wherein the plurality of semiconductor chips are vertically stacked and sequentially offset horizontally; a lower redistribution structure spaced apart from the semiconductor chip stack; a connection structure between the lower redistribution structure and the semiconductor chip stack, wherein the connection structure is in contact with the lower redistribution structure; conductive wires connecting the plurality of chip pads to the connection structure; and an encapsulant surrounding at least a portion of a surface of the semiconductor chip stack, an upper surface of the connection structure, and a side surface of the conductive wires, wherein the connection structure includes a connection insulating layer, a connection pattern in contact with the connection insulating layer, and metal layers, wherein the connection pattern includes a connection line pattern and a connection via pattern, wherein the lower redistribution structure includes a redistribution insulating layer and a redistribution pattern, wherein the encapsulant is between the semiconductor chip stack and the lower redistribution structure, wherein the metal layers correspond to the conductive wires, are on a first surface of the connection via pattern, and are between the conductive wires and the connection via pattern, wherein each of the metal layers includes a first surface and a second surface opposite to the first surface, wherein the metal layers are not in contact with the encapsulant, wherein side surfaces of the metal layers are in contact with the connection insulating layer, the first surfaces of the metal layers are in contact with the conductive wires, and the second surfaces of the metal layers are in contact with the connection via pattern, wherein the connection pattern includes a connection seed layer between the connection pattern, the metal layers, and the connection insulating layer, wherein the connection seed layer extends along a surface of the connection pattern, wherein the connection seed layer is spaced apart from the encapsulant, wherein the connection insulating layer is between the connection seed layer and the encapsulant, wherein a vertical level of the first surfaces of the metal layers is the same as a vertical level of a surface of the connection insulating layer, wherein a horizontal width of a surface of the connection via pattern in contact with a first metal layer of the metal layers is greater than a horizontal width of the second surface of the first metal layer, and wherein the connection via pattern has a tapered shape in which a horizontal width of the connection via pattern decreases in a direction toward the surface in contact with the first metal layer, and wherein an outer edge of a planar shape of the second surface of the first metal layer is inside an outer edge of a planar shape of a surface of the connection via pattern in contact with the second surface of the first metal layer.

According to an aspect of the disclosure, a method of manufacturing a semiconductor package includes: forming a semiconductor chip stack by stacking a plurality of semiconductor chips; connecting first ends of conductive wires to a plurality of chip pads on the plurality of semiconductor chips, wherein the conductive wires extend away from the plurality of chip pads; forming an encapsulant surrounding the conductive wires and the semiconductor chip stack; removing a portion of the encapsulant and a portion of each of the conductive wires; forming metal layers on second ends of the conductive wires; forming a connection insulating layer covering upper surfaces of the encapsulant and the metal layers; forming a connection pattern in contact with the metal layers; and forming a lower redistribution structure on the connection insulating layer and the connection pattern.

According to an aspect of the disclosure, a method of manufacturing a semiconductor package includes: placing, on a first carrier, a first semiconductor chip having an adhesive layer on a back surface of the first semiconductor chip; forming a semiconductor chip stack including a plurality of semiconductor chips by placing a second semiconductor chip laterally offset from the first semiconductor chip on the first semiconductor chip; connecting first ends of conductive wires to a plurality of chip pads provided in the plurality of semiconductor chips, wherein the conductive wires extend away from the plurality of chip pads; forming an encapsulant surrounding the conductive wires and the semiconductor chip stack; removing portions of the encapsulant and the conductive wires; forming metal layers on second ends of the conductive wires, wherein the metal layers include a first surface and a second surface opposite to the first surface; forming a connection insulating layer covering upper surfaces of the encapsulant and the metal layers; forming a plurality of first via holes which include the second surfaces of the metal layers and surfaces that are coplanar with the second surfaces; forming a connection seed layer conformally covering a surface of the plurality of first via holes and an upper surface of the connection insulating layer; forming a connection pattern including a connection via pattern and a connection line pattern; and forming a lower redistribution structure on the connection insulating layer and the connection pattern.

According to an aspect of the disclosure, a method of manufacturing a semiconductor package includes: placing, on a first carrier, a first semiconductor chip having an adhesive layer on a back surface of the first semiconductor chip; forming a semiconductor chip stack including a plurality of semiconductor chips by placing a second semiconductor chip laterally offset from the first semiconductor chip on the first semiconductor chip; connecting first ends of conductive wires to a plurality of chip pads provided in the plurality of semiconductor chips, wherein the conductive wires extend away from the plurality of chip pads; forming an encapsulant surrounding the conductive wires and the semiconductor chip stack; removing portions of the encapsulant and the conductive wires; forming metal layers on second ends of the conductive wires through an electroless plating process, wherein the metal layers include a first surface and a second surface opposite to the first surface; forming a connection insulating layer covering upper surfaces of the encapsulant and the metal layers; forming a plurality of first via holes which include the second surfaces of the metal layers and surfaces that are coplanar with the second surfaces; forming a connection seed layer conformally covering a surface of the plurality of first via holes and an upper surface of the connection insulating layer; forming a resist pattern including a guide opening for forming a connection pattern on the connection seed layer; forming the connection pattern including a connection via pattern and a connection line pattern inside the guide opening through an electroless plating process or a sputtering process; removing the resist pattern and a portion of the connection seed layer on which the connection pattern is not formed; and forming a lower redistribution structure on the connection insulating layer and the connection pattern, wherein the metal layers do not contact the encapsulant, and side surfaces of the metal layers contact the connection insulating layer.

According to an aspect of the disclosure, a method of manufacturing a semiconductor package includes: forming a semiconductor chip stack by stacking a plurality of semiconductor chips; connecting first ends of conductive wires to a plurality of chip pads on the plurality of semiconductor chips, wherein the conductive wires extend away from the plurality of chip pads; forming an encapsulant surrounding the conductive wires and the semiconductor chip stack; removing a portion of the encapsulant and a portion of each of the conductive wires; forming metal layers on second ends of the conductive wires; forming a connection insulating layer covering upper surfaces of the encapsulant and the metal layers; forming a connection pattern in contact with the metal layers; and forming a lower redistribution structure on the connection insulating layer and the connection pattern.

The forming the semiconductor chip stack may further include stacking the plurality of semiconductor chips in a sequentially and horizontally offset arrangement, and the method may further include forming the conductive wires between the plurality of chip pads and the metal layers, wherein the conductive wires respectively connect the plurality of chip pads to the metal layers.

The metal layers may not contact the encapsulant, and the side surfaces of the metal layers may contact the connection insulating layer.

The forming the metal layers may include forming the metal layers using an electroless plating process.

The metal layers may include at least one of nickel (Ni), gold (Au), platinum (Pt), molybdenum (Mo), palladium (Pd), and copper (Cu), or a combination of at least two thereof.

Each of the plurality of metal layers may include a first surface and a second surface opposite to the first surface, and the forming the connection pattern may include: forming a plurality of first via holes which include the second surfaces of the metal layers and surfaces that are coplanar with the second surfaces; forming a connection seed layer conformally covering a surface of the plurality of first via holes and an upper surface of the connection insulating layer; and forming the connection pattern including a connection via pattern and a connection line pattern.

The connection seed layer may be spaced apart from the encapsulant, and a horizontal width of the connection via pattern may decrease in a direction toward the encapsulant.

The connection pattern may include a first hole which is indented from a first surface of the connection pattern to a second surface of the connection pattern where the connection via pattern is provided.

The connection pattern may include third surfaces in contact with the second surfaces of the metal layers, and a horizontal width of the third surfaces of the connection pattern may be greater than a horizontal width of the metal layers.

A vertical thickness of the connection insulating layer may be equal to a sum of a vertical thickness of a metal layer of the metal layers and a height of the connection via pattern protruding from the connection pattern.

The plurality of chip pads may correspond to the metal layers and the conductive wires may connect the plurality of chip pads to the metal layers, respectively.

The forming the semiconductor chip stack may further include stacking the plurality of semiconductor chips such that a front surface of each of the plurality of semiconductor chips adjacent to an active surface of a semiconductor device faces the connection insulating layer.

The removing the portions of the encapsulant and the conductive wires may cause a surface of the encapsulant to be spaced apart from surfaces of the plurality of semiconductor chips adjacent to the surface of the encapsulant.

A horizontal width of each of the metal layers may be the same as a horizontal width of the conductive wires respectively corresponding to the metal layers.

According to an aspect of the disclosure, a method of manufacturing a semiconductor package includes: placing, on a first carrier, a first semiconductor chip having an adhesive layer on a back surface of the first semiconductor chip; forming a semiconductor chip stack including a plurality of semiconductor chips by placing a second semiconductor chip laterally offset from the first semiconductor chip on the first semiconductor chip; connecting first ends of conductive wires to a plurality of chip pads provided in the plurality of semiconductor chips, wherein the conductive wires extend away from the plurality of chip pads; forming an encapsulant surrounding the conductive wires and the semiconductor chip stack; removing portions of the encapsulant and the conductive wires; forming metal layers on second ends of the conductive wires, wherein the metal layers include a first surface and a second surface opposite to the first surface; forming a connection insulating layer covering upper surfaces of the encapsulant and the metal layers; forming a plurality of first via holes which include the second surfaces of the metal layers and surfaces that are coplanar with the second surfaces; forming a connection seed layer conformally covering a surface of the plurality of first via holes and an upper surface of the connection insulating layer; forming a connection pattern including a connection via pattern and a connection line pattern; and forming a lower redistribution structure on the connection insulating layer and the connection pattern.

The metal layers may not contact the encapsulant and side surfaces of the metal layers may contact the connection insulating layer, and the forming of the metal layers may include forming the metal layers using an electroless plating process.

An outer edge of a planar shape of the second surface of a first metal layer of the metal layers may be located inside an outer edge of a planar shape of a surface of the connection via pattern in contact with the second surface of the first metal layer.

The metal layers may include at least one of nickel (Ni), gold (Au), platinum (Pt), molybdenum (Mo), palladium (Pd), and copper (Cu), or a combination of at least two of Ni, Au, Pt, Mo, Pd, and Cu.

The forming the semiconductor chip stack may further include stacking the plurality of semiconductor chips such that a front surface of each of the plurality of semiconductor chips adjacent to an active surface of a semiconductor device faces the connection insulating layer, and a planar shape of the first surfaces of the metal layers may be the same as a planar shape of surfaces of the conductive wires in contact with the first surfaces of the metal layers.

According to an aspect of the disclosure, a method of manufacturing a semiconductor package includes: placing, on a first carrier, a first semiconductor chip having an adhesive layer on a back surface of the first semiconductor chip; forming a semiconductor chip stack including a plurality of semiconductor chips by placing a second semiconductor chip laterally offset from the first semiconductor chip on the first semiconductor chip; connecting first ends of conductive wires to a plurality of chip pads provided in the plurality of semiconductor chips, wherein the conductive wires extend away from the plurality of chip pads; forming an encapsulant surrounding the conductive wires and the semiconductor chip stack; removing portions of the encapsulant and the conductive wires; forming metal layers on second ends of the conductive wires through an electroless plating process, wherein the metal layers include a first surface and a second surface opposite to the first surface; forming a connection insulating layer covering upper surfaces of the encapsulant and the metal layers; forming a plurality of first via holes which include the second surfaces of the metal layers and surfaces that are coplanar with the second surfaces; forming a connection seed layer conformally covering a surface of the plurality of first via holes and an upper surface of the connection insulating layer; forming a resist pattern including a guide opening for forming a connection pattern on the connection seed layer; forming the connection pattern including a connection via pattern and a connection line pattern inside the guide opening through an electroless plating process or a sputtering process; removing the resist pattern and a portion of the connection seed layer on which the connection pattern is not formed; and forming a lower redistribution structure on the connection insulating layer and the connection pattern, wherein the metal layers do not contact the encapsulant, and side surfaces of the metal layers contact the connection insulating layer.

The disclosure is not limited to the foregoing, and one or more variations may be clearly understood by those skilled in the art from the description below.

### BRIEF DESCRIPTION OF DRAWINGS

The above and other aspects and features of certain embodiments of the present disclosure will be more apparent from the following description taken in conjunction with the accompanying drawings, in which:

FIG. 1 is a cross-sectional view of a semiconductor package according to one or more embodiments;

FIG. 2 is an enlarged cross-sectional view of portion A in FIG. 1;

FIG. 3A is a cross-sectional view taken along section B-B′ in FIG. 2;

FIG. 3B is a cross-sectional view taken along the same section of a semiconductor package as section B-B′ in FIG. 2;

FIG. 4 is an enlarged cross-sectional view of portion A in FIG. 1 of a semiconductor package according to one or more embodiments;

FIG. 5A is a cross-sectional view taken along section C-C′ in FIG. 4;

FIG. 5B is a cross-sectional view taken along the same section of a semiconductor package as section C-C′ in FIG. 4;

FIG. 6 is an enlarged cross-sectional view of the same section as portion A in FIG. 1 of a semiconductor package according to one or more embodiments;

FIGS. 7A, 7B and 7C are cross-sectional views of a semiconductor package to sequentially show a manufacturing method of a semiconductor package according to one or more embodiments;

FIGS. 7D, 7E, 7F, 7G, 7H, 7I, 7J and 7K are enlarged cross-sectional views of portion D in FIG. 7C sequentially showing a manufacturing method of a semiconductor package according to one or more embodiments; and

FIGS. 7L, 7M and 7N are cross-sectional views of a semiconductor package sequentially showing a manufacturing method of a semiconductor package according to one or more embodiments.

### DETAILED DESCRIPTION

Hereinafter, embodiments are described in detail with reference to the accompanying drawings, wherein like reference numerals refer to like elements throughout the specification.

Embodiments are provided to more completely explain the disclosure to those skilled in the art. The following embodiments may be modified into various other forms and the scope of the disclosure is not limited thereto. One or more embodiments are provided herein to convey the disclosure to those skilled in the art. Additionally, the thickness and size of each layer in the drawings are exaggerated for convenience and clarity of explanation, and unless specifically stated, the drawing are not drawn to scale.

In this specification, a first direction refers to an X direction and a second direction refers to a Y direction, wherein the first direction may be perpendicular to the second direction. A third direction refers to a Z direction, wherein the third direction may be perpendicular to each of the first direction and the second direction. A horizontal plane or a plane refers to an X-Y plane. An upper surface of a specific object refers to a surface located in a positive third direction with respect to the specific object and a lower surface of a specific object refers to a surface located in a negative third direction with respect to the specific object.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

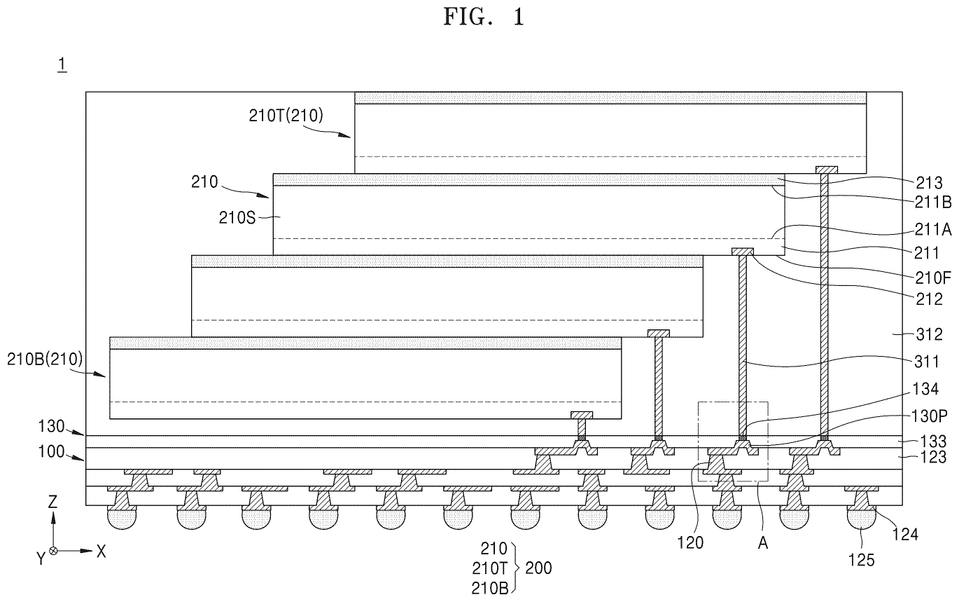

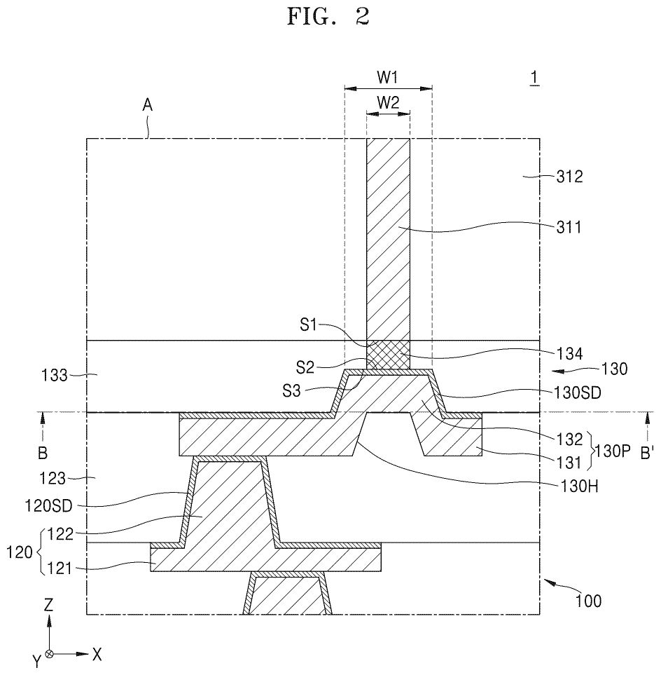

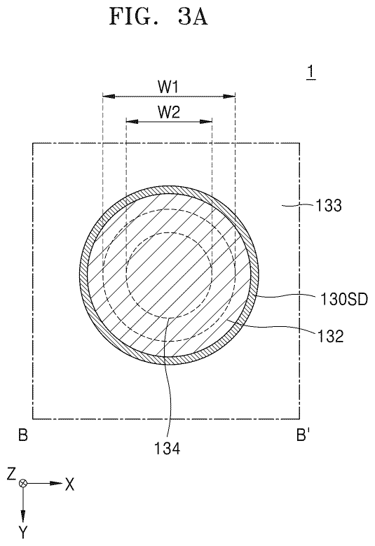

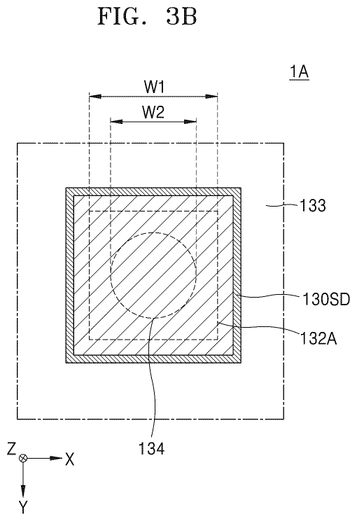

FIG. 1 is a cross-sectional view of a semiconductor package 1 according to an embodiment. FIG. 2 is an enlarged cross-sectional view of portion A in FIG. 1. FIG. 3A is a cross-sectional view taken along section B-B′ in FIG. 2. FIG. 3B is a cross-sectional view taken along the same section of a semiconductor package 1A as section B-B′ in FIG. 2.

FIGS. 1, 2, and 3A, the semiconductor package 1 according to one or more embodiments may include a semiconductor chip stack 200, a lower redistribution structure 100, and an encapsulant 312. The semiconductor chip stack 200 may include a plurality of semiconductor chips 210. Among the plurality of semiconductor chips 210, a semiconductor chip 210 closest to the lower redistribution structure 100 may be referred to as a bottom semiconductor chip 210B and a semiconductor chip 210 furthest from the lower redistribution structure 100 may be referred to as a top semiconductor chip 210T.

The plurality of semiconductor chips 210 that form the semiconductor chip stack 200 may be stacked in a stepwise arrangement. That is, the semiconductor chip stack 200 may include a plurality of semiconductor chips 210 that are offset horizontally and stacked sequentially. The plurality of semiconductor chips 210 may be arranged horizontally in an offset stacking direction. The offset stacking direction is defined as a direction in which a semiconductor chip is shifted relative to another semiconductor chip located below the semiconductor chip when semiconductor chips are stacked. For example, as shown in FIG. 1, the offset stacking direction of the plurality of semiconductor chips 210 may include a first direction (X direction).

The semiconductor chip 210 may include a semiconductor substrate 210S, an active surface 211A located adjacent to a front surface 210F of the semiconductor chip 210 (which is a surface facing the lower redistribution structure 100 of the semiconductor chip 210), and a back surface 211B of the semiconductor chip 210 located opposite to the active surface 211A. The back surface 211B of the semiconductor chip 210 may be referred to as an inactive surface. In one or more embodiments, the active surface 211A on which elements of the semiconductor chip 210 are arranged has a face down arrangement. Specifically, the active surface 211A faces down toward the lower redistribution structure 100, and the semiconductor chip stack 200 may be placed above the lower redistribution structure 100.

The semiconductor substrate 210S may include, for example, silicon (Si). Alternatively, the semiconductor substrate 210S may include a semiconductor element, such as germanium (Ge), or a compound semiconductor, such as silicon carbide (SiC), gallium arsenide (GaAs), indium arsenide (InAs), and indium phosphide (InP).

The semiconductor chip 210 may include, for example, a dynamic random-access memory (DRAM) chip, a static random-access memory (SRAM) chip, a flash memory chip, an electrically erasable and programmable read-only memory (EEPROM) chip, a phase-change random-access memory (PRAM) chip, a magnetic random-access memory (MRAM) chip, or a resistive random-access memory (RRAM) chip.

An adhesive layer 213 may be positioned on each of the back surfaces 211B of the plurality of semiconductor chips 210. The adhesive layer 213 may cover all or at least part of the back surface 211B of the semiconductor chip 210 to which the adhesive layer 213 is attached. The adhesive layer 213 on each of the back surfaces 211B of the plurality of semiconductor chips 210, except for the top semiconductor chip 210T, may be positioned between a semiconductor chip 210 and another semiconductor chip 210 stacked on top of the semiconductor chip 210. The adhesive layer 213 may include a die attach film (DAF).

A plurality of chip pads 212 may be provided on the front surfaces 210F of the semiconductor chips 210. The plurality of chip pads 212 may be electrically connected to other components within the semiconductor chip 210, such as an integrated circuit. Memory elements and multiple wiring layers may be formed on a lower surface of the semiconductor substrate 210S, i.e., the active area 211, and a plurality of chip pads 212 may be electrically connected to an integrated circuit inside the semiconductor chip 210 through the multiple wiring layers.

The encapsulant 312 may surround at least a portion of the surface of the semiconductor chip stack 200. Additionally, the encapsulant 312 may surround side surfaces of a plurality of conductive wires 311 and may contact an upper surface of the lower redistribution structure 100. A side surface of the encapsulant 312 may be vertically aligned with the side surface of the lower redistribution structure 100. An upper surface of the encapsulant 312 may have the same vertical level as an upper surface of the top semiconductor chip 210T or an adhesive layer 213 disposed on the upper surface of the top semiconductor chip 210T. In an alternative embodiment, a separate heat dissipation member may be provided to cover the upper surface of the top semiconductor chip 210T and the upper surface of the encapsulant 312. In an alternative embodiment, the encapsulant 312 may cover the upper surface of the top semiconductor chip 210T. The encapsulant 312 may be made of, for example, epoxy molding compound (EMC) or a polymer material; however, the disclosure is not limited thereto

As a plurality of semiconductor chips 210 (other than the bottom semiconductor chip 210B) are offset horizontally, that is laterally offset and exposed from the semiconductor chip 210 located immediately below each semiconductor chip 210, a portion of the front surface 210F of each semiconductor chip 210 may be in contact with the encapsulant 312. The plurality of chip pads 212 may be provided on a portion of the front surface 210F of each semiconductor chip 210 that is laterally offset and exposed from the semiconductor chip 210 located immediately below. A metal layer 134 and a connection pattern 130P, to be described below, may be provided below each of the plurality of chip pads 212. For example, the metal layer 134 and the connection pattern 130P, which are located vertically below and correspond to each of the plurality of chip pads 212, may be provided in the lower redistribution structure 100.

The lower redistribution structure 100 may be provided below the semiconductor chip stack 200. The lower redistribution structure 100 may include a connection structure 130. The connection structure 130 may be located at the top of the lower redistribution structure 100 and may face the bottom semiconductor chip 210B. The lower redistribution structure 100 located below the bottom semiconductor chip 210B may be spaced apart from the bottom semiconductor chip 210B. The encapsulant 312 may be positioned between the lower redistribution structure 100 and the bottom semiconductor chip 210B.

The connection structure 130 may include the connection pattern 130P, the metal layer 134, and a connection insulating layer 133. The connection pattern 130P may include a connection line pattern 131 and a connection via pattern 132. Additionally, the connection pattern 130P may include a connection seed layer 130SD. The metal layer 134 may be provided between the connection pattern 130P and the conductive wire 311. The connection structure 130 may be included in the lower redistribution structure 100.

The metal layer 134 provided at one end of each of the plurality of conductive wires 311 may electrically connect the connection pattern 130P to the conductive wire 311. The plurality of conductive wires 311 may be respectively connected to the plurality of chip pads 212 of the semiconductor chips 210, wherein one end of each of the plurality of conductive wires 311 may be connected to one of the plurality of chip pads 212, and the other end of each of the plurality of conductive wires 311 may be connected to one of the metal layers 134. In other words, the metal layers 134 and the plurality of chip pads 212 may correspond to each other and may be connected by the conductive wires 311. The metal layers 134 may include at least one of nickel (Ni), gold (Au), platinum (Pt), molybdenum (Mo), palladium (Pd), and copper (Cu), or a combination of two or more of Ni, Au, Pt, Mo, Pd, and Cu.

As shown in FIG. 2, side surfaces of the conductive wire 311 may be surrounded by the encapsulant 312 and a surface of the conductive wire 311 may be coplanar with a surface of the encapsulant 312. That is, the vertical level of the surface of the conductive wire 311 may be the same as the vertical level of the surface of the encapsulant 312.

The metal layer 134 may be provided on a surface of the conductive wire 311. Among the surfaces of the metal layer 134, the planar shape of a first surface S1 of the metal layer 134 in contact with the conductive wire 311 may match the planar shape of the surface of the conductive wire 311 in contact with the first surface S1 thereof. Accordingly, the side surface of the metal layer 134 may be aligned with the side surface of the conductive wire 311. Alternatively, the horizontal width of the first surface S1 of the metal layer 134 may be the same as the horizontal width of the surface of the conductive wire 311 in contact with the first surface S1 of the metal layer 134. Accordingly, the side surfaces of the metal layer 134 may be in contact with the connection insulating layer 133 but the metal layer 134 may not be in contact with the encapsulant 312.

A second surface S2 opposite to the first surface S1 of the metal layer 134 may be in contact with the connection pattern 130P. For example, the second surface S2 of the metal layer 134 may contact a third surface S3, which is part of the upper surface of the connection via pattern 132. The third surface S3 of the connection via pattern 132 may include a flat surface in contact with the second surface S2 of the metal layer 134.

The planar shape of the third surface S3 of the connection via pattern 132 may be greater than the planar shape of the second surface S2 of the metal layer 134. Alternatively, a first width W1, which is a horizontal width of the third surface S3 of the connection via pattern 132, may be greater than a second width W2 of the second surface S2 of the metal layer 134.

The planar shape of the second surface S2 of the metal layer 134 may be located inside the planar shape of the third surface S3 of the connection via pattern 132. That is, as shown in FIG. 3A, an outer edge of the metal layer 134 (indicated by a dashed line) may be located inside an outer edge of the connection via pattern 132 (indicated by a dashed line). Additionally, the cross-sectional shape of the connection via pattern 132 and the cross-sectional shape of the metal layer 134 may be circular.

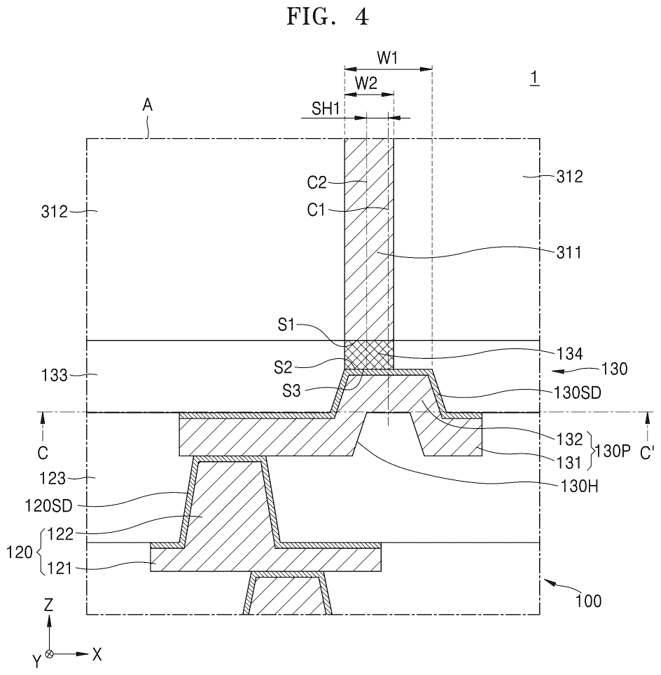

The first width W1, which is the horizontal width of the third surface S3 of the connection via pattern 132, may be greater than the second width W2 of the second surface S2 of the metal layer 134, and the planar shape of the second surface S2 of the metal layer 134 may be located inside the planar shape of the third surface S3 of the connection via pattern 132. Consequently, the risk due to misalignment that occurs in the actual manufacturing process of the semiconductor package 1 may be reduced. In other words, although the center of the second surface S2 of the metal layer 134 and the center of the third surface S3 of the connection via pattern 132 may not coincide and may shift within a certain range, the electrical connection between the metal layer 134 and the connection via pattern 132 may nevertheless be stably maintained. A more detailed explanation thereof may be provided below with reference to FIG. 4.

While contacting the surface of the encapsulant 312, the connection insulating layer 133 may contact the side surfaces of the metal layer 134 and the connection pattern 130P. The connection insulating layer 133 may be made of, for example, photo imageable dielectric (PID) or photosensitive polyimide (PSPI).

The connection via pattern 132 may be indented into a portion of the thickness of the connection insulating layer 133. That is, the connection via pattern 132 may be formed in the connection insulating layer 133 so that the connection insulating layer 133 is indented from a surface of the connection insulating layer 133 toward the inside thereof. However, as the depth of the connection via pattern 132 from the surface of the connection insulating layer 133 is less than the vertical thickness of the connection insulating layer 133, the connection via pattern 132 does not completely pass through the connection insulating layer 133. The sum of the depth of the connection via pattern 132 from the surface of the connection insulating layer 133 and the thickness of the metal layer 134 may be equal to the thickness of the connection insulating layer 133.

The connection line pattern 131 may be placed on a surface of the connection insulating layer 133. For example, as shown in FIG. 2, the connection line pattern 131 may extend from the connection via pattern 132 on the lower surface of the connection insulating layer 133. The connection line pattern 131 may be integrated with the connection via pattern 132. The connection pattern 130P may include metal, such as Cu, aluminum (Al), tungsten (W), titanium (Ti), tantalum (Ta), indium (In), Mo, manganese (Mn), cobalt (Co), tin (Sn), Ni, magnesium (Mg), rhenium (Re), beryllium (Be), gallium (Ga), ruthenium (Ru), or an alloy thereof, but the disclosure is not limited thereto.

In the connection line pattern 131, a first hole 130H which is formed in the connection line pattern 131 and indented toward the connection via pattern 132 may be provided opposite to where the connection via pattern 132 is provided. The first hole 130H, opposite to where the connection via pattern 132 is provided, may be formed concave inward from the surface of the connection line pattern 131 toward the connection via pattern 132 within the extent to which the connection via pattern 132 protrudes. The first hole 130H may be a process characteristic that occurs in the process of forming the connection pattern 130P.

The connection seed layer 130SD may be provided between the connection pattern 130P and the metal layer 134, and between the connection pattern 130P and the redistribution insulating layer 123. The connection seed layer 130SD may have a shape extending along the upper surface of the connection pattern 130P. The connection seed layer 130SD, which is the basis of the connection pattern 130P, may be formed, for example, by an electroless plating or sputtering process.

The connection seed layer 130SD may be separated from the encapsulant 312. The metal layer 134 or the connection insulating layer 133 may be positioned between the connection seed layer 130SD and the encapsulant 312. For example, unlike the one or more embodiments of semiconductor package 1 described above, when the metal layer 134 is not provided, a seed layer for forming a redistribution pattern should be formed in the encapsulant. In this case, the seed layer may be peeled off from the encapsulant because the adhesion between the encapsulant and the seed layer is not guaranteed. In addition, a sputtering process or an electroless plating process must be performed to form a seed layer in the encapsulant. When this process is performed on the encapsulant, unintended contaminants may be generated due to the encapsulant and contaminate the process equipment such that the contaminants may be included in the semiconductor package including wiring to be formed in the seed layer. The inclusion of the metal layer 134 mitigates these issues.

In the semiconductor package 1 according to one or more embodiments, the encapsulant 312 may be spaced apart from the connection seed layer 130SD by providing the metal layer 134 and the connection insulating layer 133 in between, thereby preventing the generation of contaminants. Additionally, by not forming the seed layer 130SD in the encapsulant 312, interfacial peeling between the encapsulant 312 and the seed layer 130SD may be prevented. In other words, contamination of the semiconductor package 1 and manufacturing facilities may be prevented through the semiconductor package 1 according to one or more embodiments, thereby improving reliability of the semiconductor package 1.

In one or more embodiments, the lower redistribution structure 100, including the connection structure 130, may be formed through a redistribution process. The process of forming the connection structure 130 may be included in the redistribution process of forming the lower redistribution structure 100 and the process of forming the lower redistribution structure 100 and the connection structure 130 may be described below with reference to the drawings.

The lower redistribution structure 100 may include the redistribution insulating layer 123 and the plurality of redistribution patterns 120. The redistribution insulating layer 123 may surround the plurality of redistribution patterns 120. In one or more embodiments, the lower redistribution structure 100 may include a plurality of stacked redistribution insulating layers 123. The redistribution insulating layers 123 may be formed of, for example, PID or PSPI.

A passivation layer may be provided on the lower surface of the lower redistribution structure 100. The passivation layer protects the lower redistribution structure 100, may be made of polymer, and may cover at least part of the lower surface and side surfaces of each of the plurality of external connection pads 124.

The plurality of redistribution patterns 120 may include a plurality of redistribution line patterns 121 and a plurality of redistribution via patterns 122. The plurality of redistribution patterns 120 may include, for example, Cu, Al, W, Ti, Ta, In, Mo, Mn, Co, Sn, Ni, Mg, Re, Be, Ga, Ru, or an alloy thereof, but the disclosure is not limited thereto.

The plurality of redistribution line patterns 121 may be disposed on at least one of the upper and lower surfaces of the redistribution insulating layer 123. For example, when the lower redistribution structure 100 includes the plurality of stacked redistribution insulating layers 123, the plurality of redistribution line patterns 121 may be positioned between the upper surface of the uppermost redistribution insulating layer 123, the lower surface of the lowermost redistribution insulating layer 123, and neighboring redistribution insulating layers 123.

The plurality of redistribution via patterns 122 may penetrate the redistribution insulating layer 123 and may be connected to some of the plurality of redistribution line patterns 121. In one or more embodiments, the plurality of redistribution via patterns 122 may have a tapered shape in which the horizontal width thereof decreases in a direction toward the encapsulant 312. Likewise, the plurality of redistribution via patterns 122 may have a tapered shape in which the horizontal width thereof increases as the distance from the semiconductor chip stack 200 increases.

In one or more embodiments, some of the plurality of redistribution line patterns 121 may be integrated with some of the plurality of redistribution via patterns 122. For example, the redistribution line pattern 121 may be integrated with the redistribution via pattern 122 in contact with the lower surface of the redistribution line pattern 121. The redistribution seed layer 120SD may be positioned between redistribution pattern 120 and the redistribution insulating layer 123. The redistribution seed layer 120SD may be used to form the redistribution pattern 120 in the redistribution process.

Some of the plurality of redistribution patterns 120, positioned adjacent to the lower surface of the lower redistribution structure 100, may be referred to as a plurality of external connection pads 124. Alternatively, the plurality of external connection pads 124 may be some of the plurality of redistribution line patterns 121 arranged adjacent to the lower surface of the lower redistribution structure 100.

A plurality of external connection terminals 125 may be attached to the plurality of external connection pads 124, respectively. The plurality of external connection terminals 125 may connect the semiconductor package 1 to the outside. In one or more embodiments, the plurality of external connection terminals 125 may be solder bumps or solder balls.

As shown in FIG. 3B, unlike FIG. 3A, the cross-sectional shape of the connection via pattern 132A may be square and the cross-sectional shape of the metal layer 134 may be circular. In this case, as described above, the planar shape of the second surface S2 of the metal layer 134 may be located inside the planar shape of the third surface S3 of the connection via pattern 132A. That is, as shown in FIG. 3B, an outer edge of the metal layer 134 which is circular and indicated by a dashed line may be located inside an outer edge of the connection via pattern 132A which is square and indicated by a dashed line.

The first width W1, which is the horizontal width of the third surface S3 of the connection via pattern 132, may be greater than the second width W2 of the second surface S2 of the metal layer 134, and the planar shape of the second surface S2 of the metal layer 134 may be located inside the planar shape of the third surface S3 of the connection via pattern 132. Consequently, the risk due to misalignment that occurs in the actual manufacturing process of the semiconductor package 1A may be reduced. Although the center of the second surface S2 of the metal layer 134 and the center of the third surface S3 of the connection via pattern 132 may not coincide and may shift within a certain range, the electrical connection between the metal layer 134 and the connection via pattern 132 may nevertheless be stably maintained. A more detailed explanation thereof may be provided below with reference to FIG. 4.

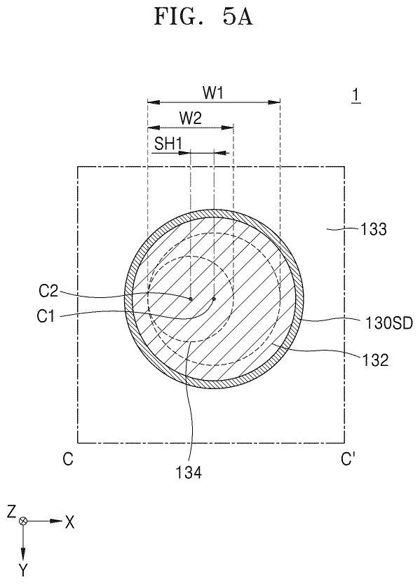

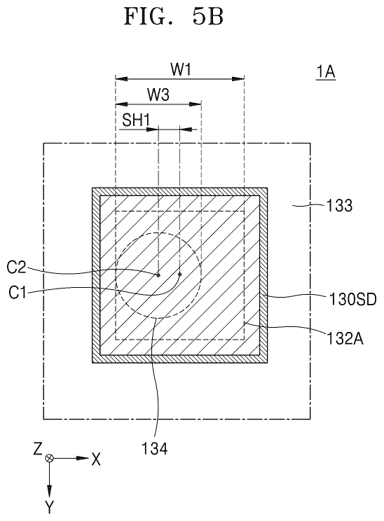

FIG. 4 is an enlarged cross-sectional view of portion A in FIG. 1 of a semiconductor package 1 according to one or more embodiments. FIG. 5A is a cross-sectional view taken along section C-C′ in FIG. 4. FIG. 5B is a cross-sectional view taken along the same section of a semiconductor package 1A as section C-C′ in FIG. 4.

Referring to FIGS. 4 and 5A, since the conductive wire 311 is integrated with the metal layer 134, the side surfaces of the conductive wire 311 and the side surfaces of the metal layer 134 may be aligned vertically. However, misalignment may occur during the redistribution process of the semiconductor package 1. For example, as shown in FIG. 4, a second center C2, which represents the center of the metal layer 134 and the conductive wire 311, and a first center C1, which represents the center of the connection via pattern 132, may not coincide, resulting in misalignment. Since the first width W1 of the connection via pattern 132 is greater than the second width W2 of the conductive wire 311 and the metal layer 134, a first shift SH1, which is a horizontally offset value between the first center Cl and the second center C2, may allow misalignment within a half of a value obtained by subtracting the second width W2 from the first width W1.

For example, as shown in FIGS. 4 and 5A, when the outer edge of the second surface S2 of the metal layer 134 is located inside and is in contact with the outer edge of the third surface S3 of the connection via pattern 132, the first shift SH1 may have the maximum value. When the outer edge of the second surface S2 of the metal layer 134 is in contact with the outer edge of the third surface S3 of the connection via pattern 132, the first shift SH1 may have the maximum value which is a half of a value obtained by subtracting the second width W2 from the first width W1.

Within semiconductor package 1, there are multiple connection relationships between the conductive wire 311, metal layer 134, and connection via pattern 132. In some of the connection relationships, the outer edge of the second surface S2 of the metal layer 134 may be in contact with the outer edge of the third surface S3 of the connection via pattern 132. Therefore, the semiconductor package 1 according to one or more embodiments may prevent contamination of the above-described semiconductor package and manufacturing facilities, improve the reliability of the semiconductor package, and reduce the risk of misalignment that may occur during the redistribution process.

Referring to FIG. 5B, the cross-sectional shape of the connection via pattern 132A may be square and the cross-sectional shape of the metal layer 134 may be circular. When a metal layer 134 with a circular cross-sectional shape is formed within a connection via pattern 132A with a square cross-sectional shape, and the outer edge of the second surface S2 of the metal layer 134 is in contact with the outer edge of the third surface S3 of the connection via pattern 132, the first shift SH1 may have a maximum value which is a half of a value obtained by substituting the second width W2 from the first width W1. In some of the multiple connection relationships between the conductive wire 311, the metal layer 134, the connection via pattern 132, and the outer edge of the second surface S2 of the metal layer 134 may be in contact with the outer edge of the third surface S3 of the connection via pattern 132 (see semiconductor package 1A). That is, as shown in FIG. 3B, the outer edge of the metal layer 134 which is circular and indicated by the dashed line may be located inside the outer edge of the connection via pattern 132A which is rectangular and indicated by the dashed line.

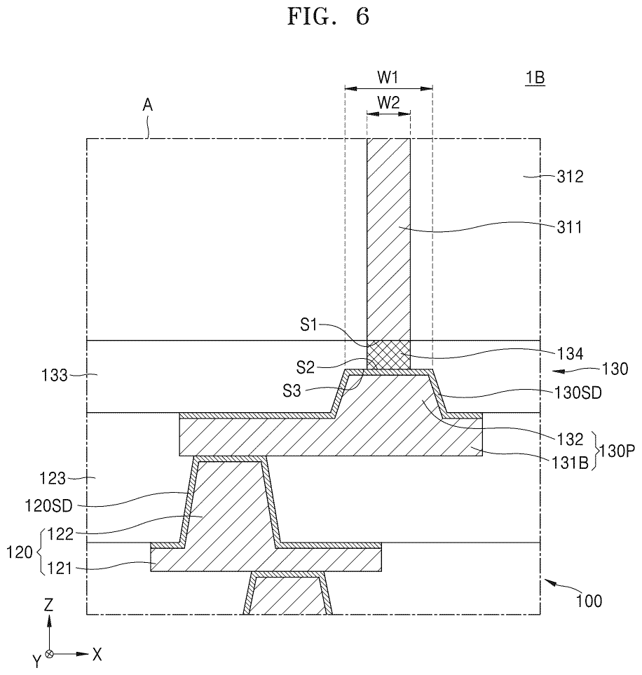

FIG. 6 is an enlarged cross-sectional view of the same section as portion A in FIG. 1 of a semiconductor package 1B according to an embodiment. Most of the components that make up the semiconductor package 1B described below and the materials that make up the components are substantially the same or similar to those of the semiconductor package 1 described previously with reference to FIGS. 1 and 2. Therefore, for convenience of explanation, the semiconductor package 1B may be explained focusing on the differences between the semiconductor package 1B and the semiconductor package 1.

Referring to FIG. 6, unlike the semiconductor package 1 of FIG. 2 in which the first hole 130H indented toward the connection via pattern 132 is provided in the connection line pattern 131, opposite to where the connection via pattern 132 is provided, in the semiconductor package 1B of FIG. 6, a surface of the connection line pattern 131B, opposite to where the connection via pattern 132 is provided, among surfaces of the connection line pattern 131B, may be flat without grooves. The flat surface without grooves, opposite to where the connection via pattern 132 is provided, among the surfaces of the connection line pattern 131B, may vary depending on the process of forming the connection pattern 130P.

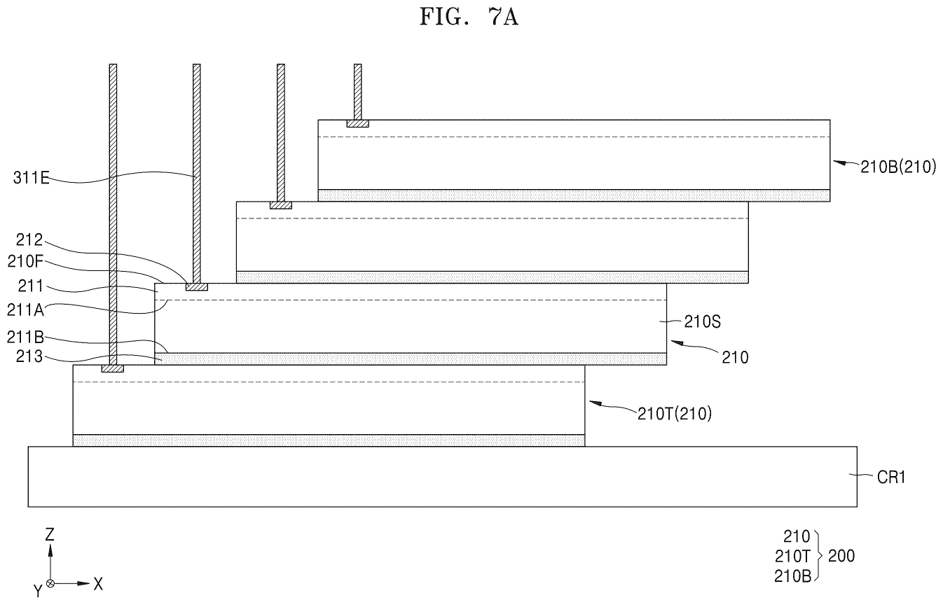

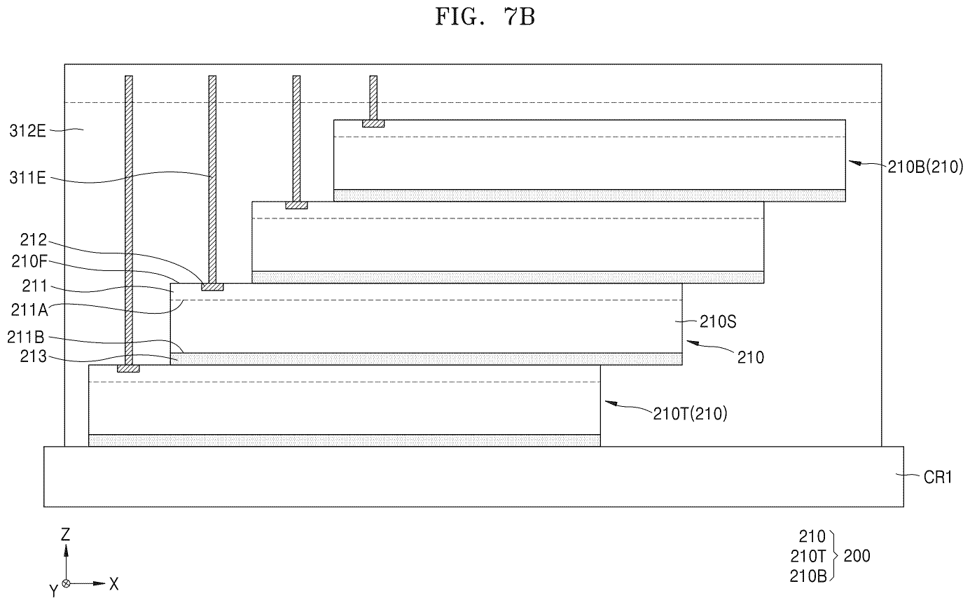

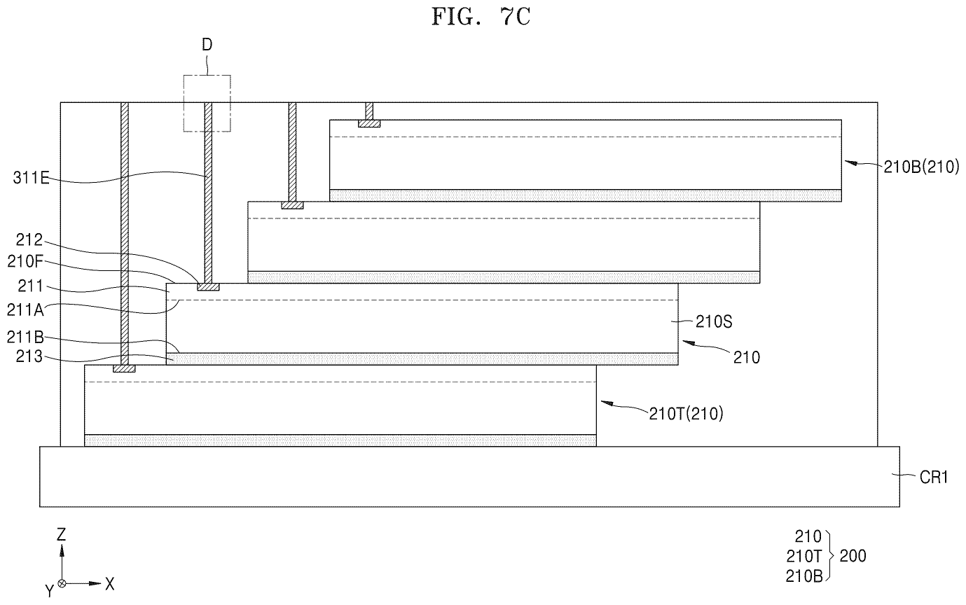

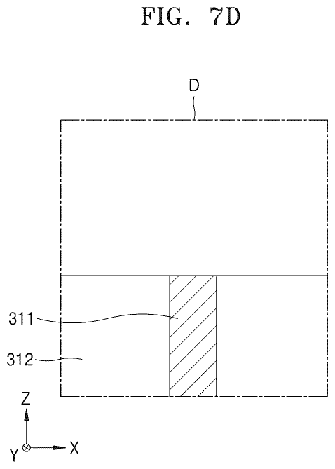

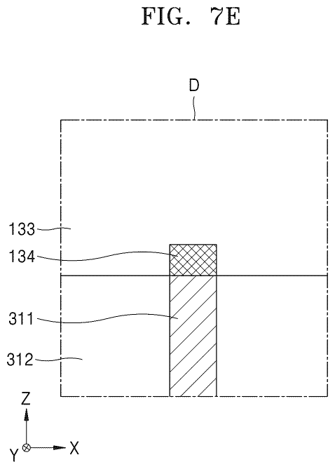

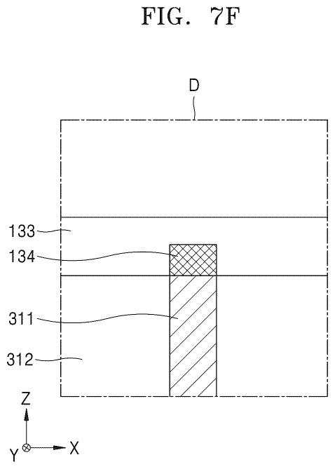

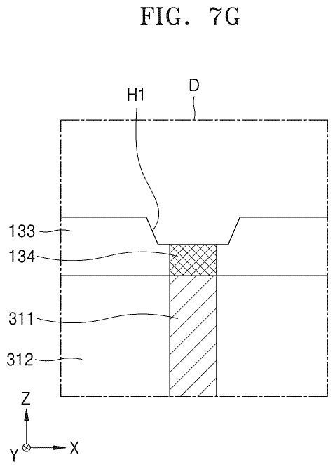

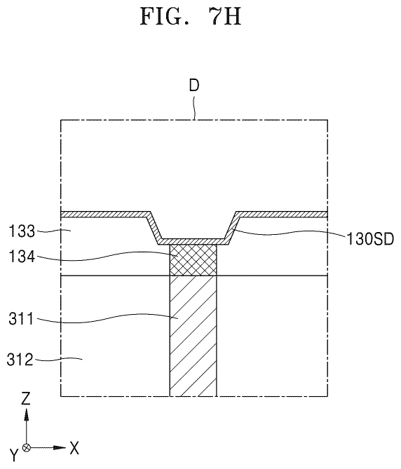

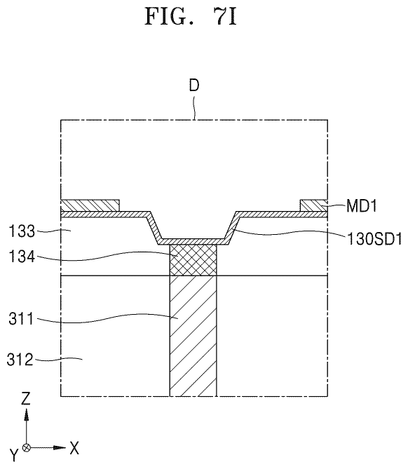

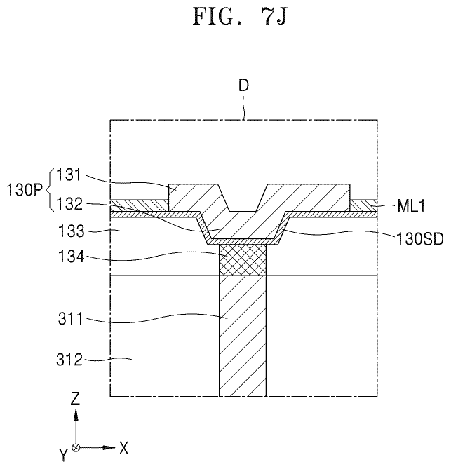

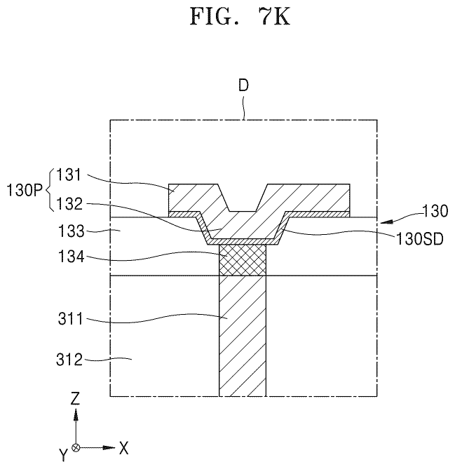

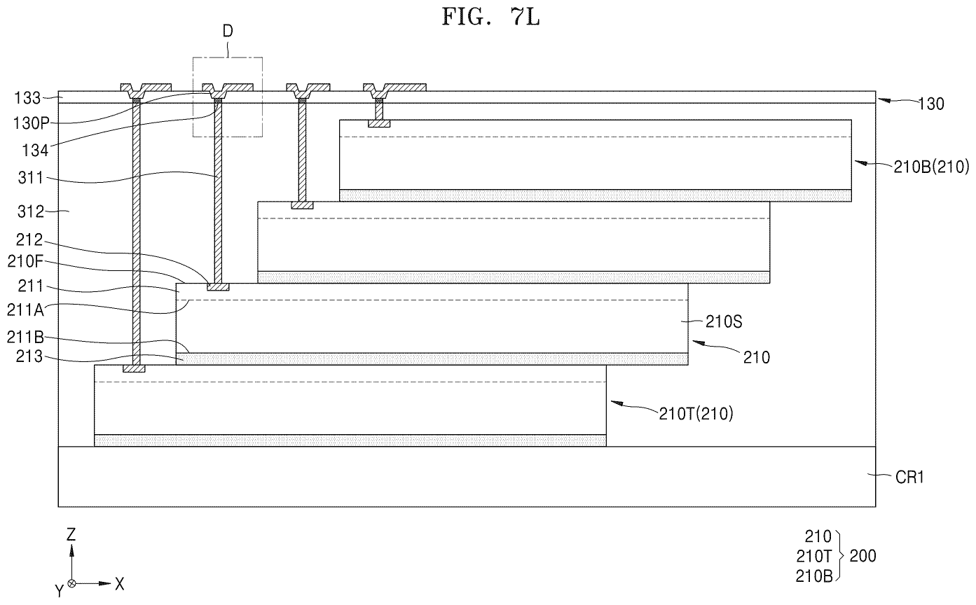

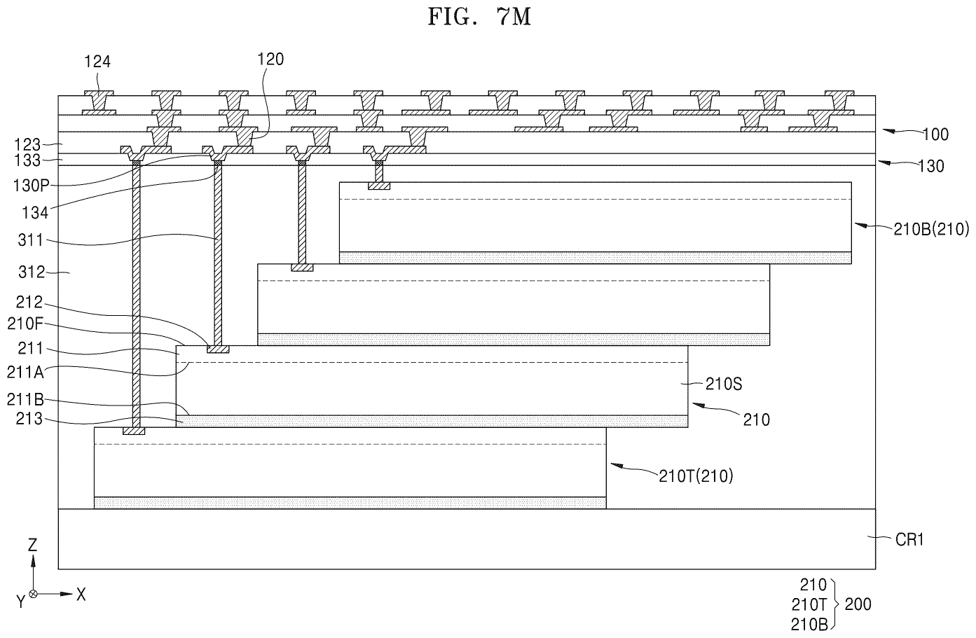

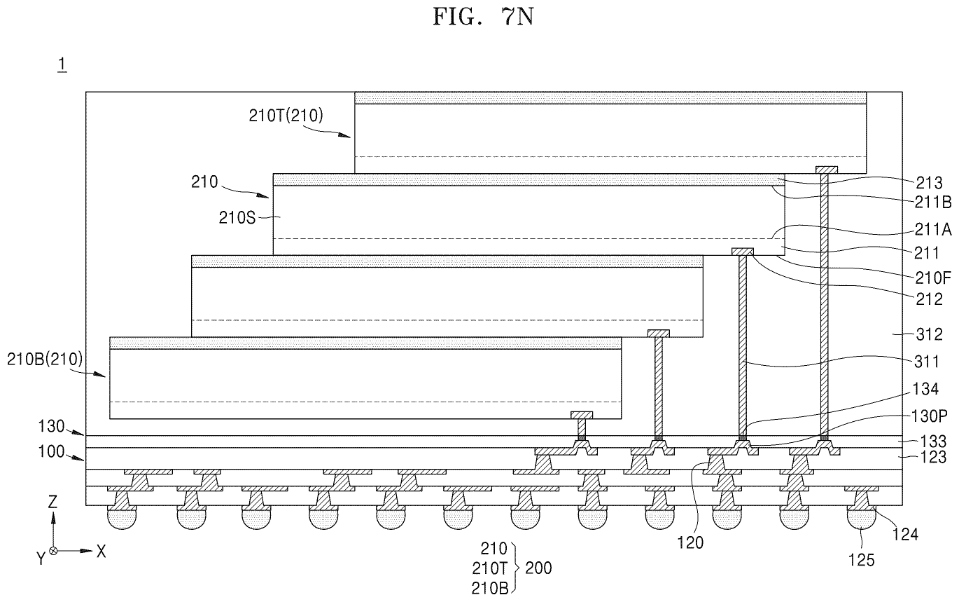

FIGS. 7A to 7C are cross-sectional views of a semiconductor package to sequentially show a manufacturing method of a semiconductor package 1 according to one or more embodiments. FIGS. 7D to 7K are enlarged cross-sectional views of portion D in FIG. 7C to sequentially show a manufacturing method of a semiconductor package 1 according to one or more embodiments. FIGS. 7L to 7N are cross-sectional views of a semiconductor package to sequentially show a manufacturing method of a semiconductor package 1 according to one or more embodiments. Descriptions within the scope that overlap with the above may be omitted.

Referring to FIG. 7A, a semiconductor chip stack 200 may be placed on a first carrier CR1. The semiconductor chip stack 200 may include a plurality of semiconductor chips 210 and an adhesive layer 213 may be positioned on a back surface 211B of each semiconductor chip 210.

The semiconductor chip stack 200 may include the plurality of semiconductor chips 210 that are offset horizontally and stacked sequentially. For example, the plurality of semiconductor chips 210 may have an offset stacking direction in the first direction (X direction). However, the semiconductor chip stack 200 is not limited to the offset stacking direction.

In one or more embodiments, conductive wires 311E may be disposed on the plurality of chip pads 212 arranged in the plurality of semiconductor chips 210, respectively. The conductive wire 311E may be ejected from a capillary. The conductive wires 311E may extend vertically upward from the plurality of chip pads 212 provided in the plurality of semiconductor chips 210, respectively, included in the semiconductor chip stack 200. As the conductive wires 311E extend from the plurality of chip pads 212, wire balls having a horizontal width greater than the thickness of the conductive wires 311E may be formed from the plurality of chip pads 212. The wire balls integrated with the conductive wires 311E may provide contact between the plurality of chip pads 212 and the conductive wires 311E.

The conductive wires 311E may be connected to the plurality of chip pads 212 through the capillary. The capillary may cut the conductive wire 311E when the conductive wire 311E is ejected to a set length. The set length may vary depending on each location of the plurality of semiconductor chips 210. For example, the length of the conductive wire 311E connected to the chip pad 212 of the bottom semiconductor chip 210B may be less than the lengths of the conductive wires 311E connected to the other semiconductor chips 210 and the length of the conductive wire 311E connected to the chip pad 212 of the top semiconductor chip 210T may be greater than the lengths of the conductive wires 311E connected to the other semiconductor chips 210.

Referring to FIG. 7B, an encapsulant 312E may surround the semiconductor chip stack 200 placed on the first carrier CR1 and the conductive wires 311E. The encapsulant 312E may be formed collectively for multiple semiconductor chip stacks 200 placed on the first carrier CR1. However, this drawing shows the encapsulant 312E formed for one semiconductor chip stack 200. The encapsulant 312E may include a molding member including an EMC or a polymer material and may further include a filler. As shown in FIG. 7B, the encapsulant 312E may cover the upper surfaces of the conductive wires 311E, or, unlike the drawing, the upper surfaces of the conductive wires 311E may be coplanar with the upper surface of the encapsulant 312E.

Referring to FIGS. 7C and 7D, a portion of the encapsulant 312E and a portion of the conductive wire 311E may be removed. The portion of the encapsulant 312E and the portion of the conductive wire 311E which are above from a dashed line in FIG. 7B may be removed. For example, the portion of the encapsulant 312E and the portion of the conductive wire 311E may be removed through chemical mechanical polishing (CMP). Through the CMP, the upper surface of the encapsulant 312 may be coplanar with the upper surfaces of the conductive wires 311.

Referring to FIG. 7E, the metal layer 134 may be formed on a surface of the conductive wire 311 exposed to the upper surface of the encapsulant 312. The metal layer 134 may be formed by electroless plating, which is a plating method wherein metal ions present in a solution are reduced through a reduction reaction using a reducing agent and are deposited on the surface without applying electrical energy. The electroless plating method may be performed on the surface of the conductive wire 311 rather than the upper surface of the encapsulant 312.

Referring to FIG. 7F, the connection insulating layer 133 may be formed on the upper surface of the encapsulant 312. The connection insulating layer 133 may cover the side surfaces and the upper surface of the metal layer 134. The connection insulating layer 133 may be made of PID or PSPI. The vertical thickness of the connection insulating layer 133 may be greater than the vertical thickness of the metal layer 134.

Referring to FIG. 7G, a first via hole H1 may be formed through the process of FIG. 7F. By removing the connection insulating layer 133, the upper surface of the metal layer 134 may be exposed. The first via hole H1 may be formed by laser processing, but the disclosure is not limited thereto. In the process of forming the first via hole H1, the upper surface of the metal layer 134 may be exposed to the outside and a portion of the surface of the first via hole H1 may be coplanar with the upper surface of the metal layer 134. Due to the nature of the process of forming the first via hole H1, the first via hole H1 may have a tapered shape in which the horizontal width of the first via hole H1 increases as the distance from the conductive wire 311 increases.

Referring to FIG. 7H, an electroless plating process or a sputtering process may be performed to form the connection seed layer 130SD. The connection seed layer 130SD may be formed on the first via hole H1 and the connection insulating layer 133. The connection seed layer 130SD may conformally cover the bottom surface and side walls of the first via hole H1 and an upper surface of the connection insulating layer 133. The connection seed layer 130SD may include conductive materials. For example, the connection seed layer 130SD may include one or more materials selected from the group consisting of Cu, Ni, Pd, silver (Ag), chromium (Cr), Ti, and Au.

Referring to FIG. 7I, a resist pattern MD1 having a guide opening may be formed on the connection seed layer 130SD. The resist pattern MD1 may be formed of dry film resistor (DFR). The guide opening, to be described below, is for forming the connection pattern 130P.

Referring to FIG. 7J, as described above with reference to FIG. 7I, the connection pattern 130P may be formed in the guide opening of the resist pattern MD1. For example, in the case of electroless plating, the connection pattern 130P may be formed by performing electroless plating using the connection seed layer 130SD as an electrode. As described above, the connection pattern 130P may include the connection line pattern 131 and the connection via pattern 132. The connection line pattern 131 may be integrated with the connection via pattern 132 through a single process.

Referring to FIGS. 7K and 7L, the resist pattern MD1 may be peeled off and removed and the connection seed layer 130SD on which the connection pattern 130P is not formed may be removed by etching. The connection seed layer 130SD on which the connection pattern 130P is not formed may be selectively removed by an etching process with etch selectivity for the connection seed layer 130SD, compared to the connection pattern 130P. Therefore, as shown in FIG. 7L, the metal layer 134 may be provided on the surface of the conductive wire 311, the connection insulating layer 133 may be located on the upper surface of the encapsulant 312, and a portion of the connection insulating layer 133 may be removed to form the connection seed layer 130SD and the connection pattern 130P.

Referring to FIG. 7M, through a redistribution process, the lower redistribution structure 100 including the redistribution insulating layer 123 and the redistribution pattern 120 may be formed on the connection insulating layer 133. In the lower redistribution structure 100, the redistribution insulating layer 123 and the redistribution pattern 120 may be alternately formed according to the redistribution process. After the lower redistribution structure 100 is formed through the redistribution process, an individualization process may be performed. The individualization process may refer to cutting a semiconductor package manufactured in multiple batches into individual semiconductor packages through sawing, and the like.

Referring to FIG. 7N, the first carrier CR1 may be removed and the plurality of external connection terminals 125 may be provided to the plurality of external connection pads 124, respectively. The semiconductor package 1 according to one or more embodiments may be manufactured by sequentially going through the processes of FIGS. 7A to 7N.

While the disclosure has been particularly shown and described with reference to embodiments thereof, it will be understood that various changes in form and details may be made therein without departing from the spirit and scope of the following claims.

What is claimed is:

1. A semiconductor package comprising:
a semiconductor chip stack comprising a stack of a plurality of semiconductor chips;
a lower redistribution structure spaced apart from the semiconductor chip stack;
a connection structure between the lower redistribution structure and the semiconductor chip stack, wherein the connection structure is in contact with the lower redistribution structure;
conductive wires connecting the plurality of semiconductor chips to the connection structure; and
an encapsulant surrounding at least a portion of a surface of the semiconductor chip stack, an upper surface of the connection structure, and a side surface of the conductive wires,
wherein the connection structure comprises a connection insulating layer, a connection pattern in contact with the connection insulating layer, and metal layers,
wherein the connection pattern comprises a connection line pattern and a connection via pattern,
wherein the lower redistribution structure comprises a redistribution insulating layer and a redistribution pattern, and
wherein the metal layers correspond to the conductive wires, are on one surface of the connection via pattern, and are between the conductive wires and the connection via pattern.

2. The semiconductor package of claim 1,
wherein the metal layers are not in contact with the encapsulant,
wherein side surfaces of the metal layers are in contact with the connection insulating layer,
wherein each of the metal layers comprises a first surface and a second surface opposite to the first surface,
wherein the first surface of each of the metal layers is in contact with the a conductive wire of the conductive wires, and
wherein the second surface of each of the metal layers is in contact with the connection via pattern.

3. The semiconductor package of claim 2,
wherein the connection pattern comprises a connection seed layer,
wherein the connection seed layer is between the connection pattern, the metal layers, and the connection insulating layer and extends along a surface of the connection pattern, and
wherein the connection seed layer is spaced apart from the encapsulant and is between the connection seed layer and the encapsulant.

4. The semiconductor package of claim 2,
wherein a horizontal width of the first surface of each respective metal layer of the metal layers is the same as a horizontal width of the conductive wire which the respective metal layers are in contact with from among the conductive wires.

5. The semiconductor package of claim 2, wherein a vertical level of the first surface of each of the metal layers is the same as a vertical level of a surface of the connection insulating layer.

6. The semiconductor package of claim 2,
wherein a horizontal width of a surface of the connection via pattern in contact with a first metal layer of the metal layers is greater than a horizontal width of the second surface of the first metal layer, and
wherein the connection via pattern has a tapered shape in which a horizontal width of the connection via pattern decreases in a direction toward the surface in contact with the first metal layer.

7. The semiconductor package of claim 2, wherein an outer edge of a planar shape of the second surface of a first metal layer among the metal layers is inside an outer edge of a planar shape of a surface of the connection via pattern in contact with the second surfaces of the first metal layer.

8. The semiconductor package of claim 2, wherein an outer edge of a planar shape of the second surface of a first metal layer among the metal layers is in contact with an outer edge of a planar shape of a surface of the connection via pattern in contact with the first metal layer.

9. The semiconductor package of claim 2, wherein the connection line pattern comprises a first hole indented from a first surface of the connection line pattern to a second surface of the connection line pattern where the connection via pattern is located.

10. The semiconductor package of claim 2, wherein a surface of the connection line pattern opposite from the connection via pattern comprises a uniform flat surface.

11. The semiconductor package of claim 2, wherein a planar shape of the connection via pattern is square or circular.

12. The semiconductor package of claim 2,
wherein the plurality of semiconductor chips are offset vertically and stacked in a stepwise arrangement,
wherein the semiconductor chip stack further comprises chip pads on lower surfaces of the plurality of semiconductor chips, and
wherein the lower surfaces of the plurality of semiconductor chips face the lower redistribution structure.

13. The semiconductor package of claim 2, wherein the metal layers comprise at least one of nickel (Ni), gold (Au), platinum (Pt), molybdenum (Mo), palladium (Pd), and copper (Cu).

14. A semiconductor package comprising:
a semiconductor chip stack comprising a plurality of semiconductor chips;
a lower redistribution structure spaced apart from the semiconductor chip stack;
conductive wires connecting the plurality of semiconductor chips to the lower redistribution structure; and
an encapsulant surrounding at least a portion of a surface of the semiconductor chip stack, an upper surface of the lower redistribution structure, and a side surface of the conductive wires,
wherein the lower redistribution structure comprises a redistribution insulating layer, a redistribution pattern, a top insulating layer, a connection insulating layer, a connection pattern, and metal layers,
wherein the connection pattern comprises a connection line pattern and a connection via pattern,
wherein the top insulating layer is in contact with the encapsulant,
wherein the encapsulant is between the semiconductor chip stack and the lower redistribution structure, and
wherein the metal layers correspond to the conductive wires, are on one surface of the connection via pattern, and are between the conductive wires and the connection via pattern.

15. The semiconductor package of claim 14,
wherein each of the plurality of metal layers comprises a first surface and a second surface opposite to the first surface,
wherein the first surface of the metal layers are in contact with the conductive wires,
wherein side surfaces of the metal layers are in contact with the connection insulating layer,
wherein the second surfaces of the metal layers are in contact with the connection via pattern, and
wherein a planar shape of the first surfaces of the metal layers matches a planar shape of surfaces of the conductive wires in contact with the first surfaces.

16. The semiconductor package of claim 15,
wherein the metal layers do not contact the encapsulant,
wherein the connection via pattern comprises third surfaces, wherein the third surface are in contact with the second surfaces of the metal layers and the connection insulating layer.

17. The semiconductor package of claim 15, wherein side surfaces of each of the metal layers are vertically aligned with side surfaces of the conductive wires.

18. The semiconductor package of claim 15,
wherein the connection via pattern comprises third surfaces, wherein the third surfaces are in contact with the second surfaces of the metal layers and the connection insulating layer, and
wherein at least a portion of an outer edge of the planar shape of the first surfaces of the metal layers is inside an outer edge of the third surfaces of the connection via pattern.

19. The semiconductor package of claim 15,
wherein the connection line pattern comprises a first hole indented from opposite first surface of the connection line pattern to a second surface of the connection line pattern where the connection via pattern is provided, and
wherein a planar shape of the connection via pattern is square or circular.

20. A semiconductor package comprising:
a semiconductor chip stack comprising a plurality of semiconductor chips and a plurality of chip pads on lower surfaces the plurality of semiconductor chips, wherein the plurality of semiconductor chips are vertically stacked and sequentially offset horizontally;
a lower redistribution structure spaced apart from the semiconductor chip stack;
a connection structure between the lower redistribution structure and the semiconductor chip stack, wherein the connection structure is in contact with the lower redistribution structure;
conductive wires connecting the plurality of chip pads to the connection structure; and
an encapsulant surrounding at least a portion of a surface of the semiconductor chip stack, an upper surface of the connection structure, and a side surface of the conductive wires,
wherein the connection structure comprises a connection insulating layer, a connection pattern in contact with the connection insulating layer, and metal layers,
wherein the connection pattern comprises a connection line pattern and a connection via pattern,
wherein the lower redistribution structure comprises a redistribution insulating layer and a redistribution pattern,
wherein the encapsulant is between the semiconductor chip stack and the lower redistribution structure,
wherein the metal layers correspond to the conductive wires, are on a first surface of the connection via pattern, and are between the conductive wires and the connection via pattern,
wherein each of the metal layers comprises a first surface and a second surface opposite to the first surface, wherein the metal layers are not in contact with the encapsulant,
wherein side surfaces of the metal layers are in contact with the connection insulating layer, the first surfaces of the metal layers are in contact with the conductive wires, and the second surfaces of the metal layers are in contact with the connection via pattern,
wherein the connection pattern comprises a connection seed layer between the connection pattern, the metal layers, and the connection insulating layer,
wherein the connection seed layer extends along a surface of the connection pattern,
wherein the connection seed layer is spaced apart from the encapsulant,
wherein the connection insulating layer is between the connection seed layer and the encapsulant,
wherein a vertical level of the first surfaces of the metal layers is the same as a vertical level of a surface of the connection insulating layer,
wherein a horizontal width of a surface of the connection via pattern in contact with a first metal layer of the metal layers is greater than a horizontal width of the second surface of the first metal layer, and
wherein the connection via pattern has a tapered shape in which a horizontal width of the connection via pattern decreases in a direction toward the surface in contact with the first metal layer, and
wherein an outer edge of a planar shape of the second surface of the first metal layer is inside an outer edge of a planar shape of a surface of the connection via pattern in contact with the second surface of the first metal layer.
